(19) United States
(12) Patent Application Publication
(10) Pub. No.: US 2026/0038741 A1
(43) Pub. Date: Feb. 5, 2026

(54) MULTILAYER CERAMIC CAPACITOR AND CIRCUIT BOARD

(71) Applicant: TAIYO YUDEN CO., LTD., Tokyo (JP)

(72) Inventors: Yoshinari TAKE, Tokyo (JP); Tomoki INOUE, Tokyo (JP); Takeshi SAKASHITA, Tokyo (JP); Yuka NAITO, Tokyo (JP)

(73) Assignee: TAIYO YUDEN CO., LTD., Tokyo (JP)

(21) Appl. No.: 19/266,410

(22) Filed: Jul. 11, 2025

(30) Foreign Application Priority Data
Aug. 5, 2024 (JP) 2024-128650

(51) Int. Cl. H01G 4/30; H01G 4/232; H05K 1/18

(52) U.S. Cl. CPC H01G 4/30; H01G 4/232; H05K 1/181; H05K 2201/10015

(57) ABSTRACT

An aspect of the present invention is a multilayer ceramic capacitor comprising: a multilayer unit obtained by alternately laminating ceramic layers and internal electrodes composed primarily of metal; a cuboid element body having a pair of covering portions arranged at both ends of the stack in the laminating direction and covering surfaces of the multilayer unit, and margin portions covering at least some of the end portions of the ceramic layers, and the end portions of the internal electrodes in the multilayer unit, and connecting the pair of covering portions to each other; and a plurality of terminal electrodes electrically connected to the internal electrodes, and arranged apart from each other on at least a mounting surface out of the surfaces forming the surfaces of the element body, wherein the mounting surface is a surface facing the circuit board on which the capacitor is to be mounted, and relational expression (1) below is satisfied, where Pₒ is the porosity of a surface layer portion and Pᵢ is a porosity of an inner portion located closer to the multilayer unit than the surface layer portion in at least some of the regions in the covering portion or the margin portion

$${P}_{i} < {P}_{o} . \qquad ( 1 )$$

### CROSS-REFERENCE TO RELATED APPLICATIONS

This application claims the benefit of Japanese Application No. 2024-128650, filed Aug. 5, 2024, in the Japanese Patent Office. All disclosures of the document named above are incorporated herein by reference.

### TECHNICAL FIELD

The present invention relates to a multilayer ceramic capacitor and a circuit board.

### BACKGROUND ART

A wide variety of ceramic electronic components are used in high-frequency communication systems, such as those for mobile phones. There is demand for smaller and thinner ceramic electronic components, and smaller and thinner multilayer ceramic capacitors are being considered.

Patent Document 1 discloses a thin, damage-resistant multilayer ceramic capacitor, in which via-hole electrodes used to electrically connect internal electrode layers to each other and to electrically connect internal electrode layers to terminal electrodes are formed with a void inside. In the multilayer ceramic capacitor disclosed in Patent Document 1, terminal electrodes are formed on the flat surface of the element body (element unit).

### PRIOR ART DOCUMENTS

### Patent Documents

[Patent Document 1] JP 2020-72263 A

### SUMMARY OF THE INVENTION

### Problem to be Solved by the Invention

The multilayer ceramic capacitor disclosed in Patent Document 1 has terminal electrodes formed only on the top surface of the opposing top and bottom surfaces. In a multilayer ceramic capacitor with this structure, the exposed area of the element body is large on the bottom surface where no terminal electrodes are formed. Since the surfaces of the element body are often made of a brittle material such as a ceramic, the exposed surfaces of the element body may crack or chip when subjected to impact during handling of the multilayer ceramic capacitor or after mounting it on a circuit board. Cracks and chips on the surface of the element body can be a pathway for deleterious factors such as moisture to enter, causing a reduction in the durability and reliability of the multilayer ceramic capacitor. These circumstances call for improved surface toughness of element body surfaces in multilayer ceramic capacitors.

It is an object of the present invention to respond to this demand by providing a multilayer ceramic capacitor having improved element body surface toughness, and a circuit board on which this multilayer ceramic capacitor is mounted.

### Means for Solving the Problem

As a result of extensive research conducted to solve this problem, the present inventor discovered that the object of the present invention could be realized by giving at least some of the element body surface in a multilayer ceramic capacitor greater porosity than the inner portion. The present invention is a product of this discovery.

A first aspect of the present invention for solving this problem is a multilayer ceramic capacitor comprising: a multilayer unit obtained by alternately laminating ceramic layers and internal electrodes composed primarily of metal; a cuboid element body having a pair of covering portions arranged at both ends of the multilayer unit in the laminating direction and covering surfaces of the multilayer unit, and margin portions covering at least some of the end portions of the ceramic layers and the end portions of the internal electrodes in the multilayer unit, and connecting the pair of covering portions to each other; and a plurality of terminal electrodes electrically connected to the internal electrodes, and arranged apart from each other on at least a mounting surface out of the surfaces forming the surfaces of the element body, wherein the mounting surface is a surface facing the circuit board on which the capacitor is to be mounted, and relational expression (1) below is satisfied, where Pₒ is the porosity of a surface layer portion and Pᵢ is a porosity of an inner portion located closer to the multilayer unit than the surface layer portion in at least some of the regions in the covering portion or the margin portion.

$${P}_{i} < {P}_{o} \qquad ( 1 )$$

A second aspect of the present invention that solves this problem is a circuit board on which is mounted a multilayer ceramic capacitor according to the first aspect of the present invention.

### Effect of the Invention

The present invention is able to provide a multilayer ceramic capacitor having improved element body surface toughness, and a circuit board on which this multilayer ceramic capacitor is mounted.

### BRIEF DESCRIPTION OF THE DRAWINGS

FIG. 1 is a schematic diagram (perspective view) of the structure of the multilayer ceramic capacitor in a first embodiment of the present invention.

FIG. 2 is a cross-sectional view (LT cross-sectional view) from A-A in FIG. 1.

FIG. 3 is a diagram used to explain the method for determining the porosity in the surface layer portion, the inner layer portion, and via surface layer portion of the covering portion that forms the facing surface of the multilayer ceramic capacitor.

FIG. 4 is a diagram used to explain the method for determining the porosity of the surface layer portion and the inner portion of the margin portion of the multilayer ceramic capacitor.

FIG. 5 is a diagram used to explain the method for determining the percentage of cells with voids relative to the total number of cells in a cross section parallel to the laminating direction of the via surface layer portion in a multilayer ceramic capacitor with a via surface layer portion.

FIG. 6 is a schematic diagram (LT plan view) of the structure of the multilayer ceramic capacitor in a second embodiment of the present invention.

FIG. 7 is a schematic diagram (perspective view) of the structure of the multilayer ceramic capacitor in a third embodiment of the present invention.

### EMBODIMENT OF THE INVENTION

The configuration and effects of the present invention will now be described, including technical ideas, with reference to the accompanying drawings. However, this description includes assumptions about the operating mechanism, and the correctness of these assumptions does not limit the scope of the present invention.

### [Multilayer Ceramic Capacitor]

### First Embodiment

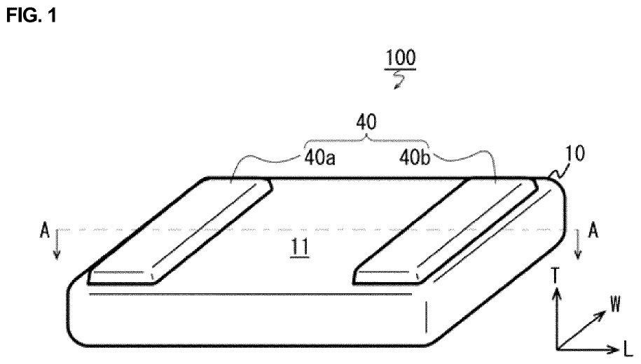

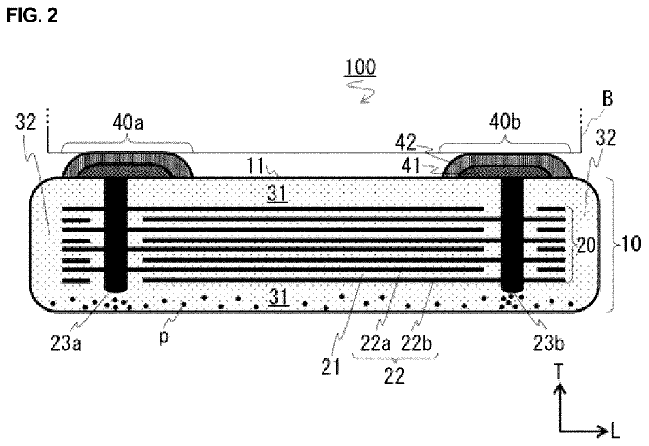

An embodiment of the multilayer ceramic capacitor in the first aspect of the present invention is shown in FIG. 1 and FIG. 2 as a first embodiment. The multilayer ceramic capacitor 100 in the first embodiment has a cuboid shape with a pair of faces each perpendicular to the three axes, namely, an L-axis in the length direction, a W-axis in the width direction, and a T-axis in the height direction, where these axes are orthogonal to each other. The cuboid is not limited to a cuboid as defined mathematically, but includes any shape that is recognizable as a cuboid after observing its overall shape. Therefore, those with edges and corners that are slightly rounded, edges that are slightly curved, and surfaces that are curved surfaces with a small curvature also fall under the category of cuboid in the present disclosure. The length (L), width (W), and height (T) dimensions of the multilayer ceramic capacitor 100 can each be set independently to any value.

Examples of dimensions for the multilayer ceramic capacitor 100 are an L-direction dimension of 200 μm or more and 2000 μm or less, a W-direction dimension of 100 μm or more and 2000 μm or less, a T-direction dimension of 30 μm or more and 220 μm or less, and a W/L ratio, or the ratio of the W-direction dimension to the L-direction dimension, of 0.3 or more and 1.0 or less. Each of these dimensions is preferably an L-direction dimension of 400 μm or more and 1200 μm or less, a W-direction dimension of 400 μm or more and 1200 μm or less, a T-direction dimension of 40 μm or more and 150 μm or less, and a W/L ratio, which is the ratio of the W-direction dimension to the L-direction dimension, of 0.4 or more and 1.0 or less. The T-direction dimension is preferably 100 μm or less, as this is less likely to be constrained by the design of the circuit board on which it is mounted.

FIG. 2 shows an example of a multilayer ceramic capacitor 100 mounted on a circuit board B. As schematically shown in the cross-sectional view in FIG. 2, the multilayer ceramic capacitor 100 in the first embodiment comprises a multilayer unit 20 obtained by alternately laminating in the T direction ceramic layers 21 and internal electrodes 22 composed primarily of metal, and an element body 10 having a pair of covering portions 31 covering the surfaces of the multilayer unit 20, and a margin portion 32 connecting the pair of covering portions 31 while covering at least some of the end portions of the ceramic layers 21 and the end portions of the internal electrodes 22 in the multilayer unit 20. The internal electrodes 22 include internal electrodes 22a of one polarity electrically connected to each other, and an internal electrode 22b of a different polarity from the internal electrode 22a electrically connected to each other.

The method of electrically connecting internal electrodes 22a to each other and internal electrodes 22b to each other is not limited. In the present embodiment, the internal electrodes 22a, 22b are connected to each other by way of via conductors 23 (23a, 23b) in the laminating direction. The via conductors 23 are located inside the element body 10, and pass through the ceramic layers 21 in the laminating direction of the multilayer unit 20. One end of the via conductors 23 reaches the covering portion 31 on the positive side in the T direction, while the other end of the via conductors 23 does not reach the covering portion 31 on the negative side in the T direction and remains covered by the covering layer 1. As in the second embodiment described below, the internal electrodes may be drawn out to the end surfaces of the element body and connected via connecting conductors on the surface of the element body. Note that while the multilayer ceramic capacitor 100 shown in FIG. 2 has two via conductors 23, the number of via conductors in the multilayer ceramic capacitor 100 of the first aspect of the present invention is not limited to this number.

The covering portions 31 are arranged on the surfaces of the element body 10 perpendicular to the T direction of the multilayer unit 20, and the margin portions 32 are arranged on the surfaces perpendicular to the W direction and perpendicular to the L direction of the multilayer unit 20. Note that, as described in the second embodiment below, when the internal electrodes are drawn from the end faces of the element body, margin portions are not provided on the end faces (draw-out faces) where the internal electrodes are drawn out.

The multilayer ceramic capacitor 100 in the first embodiment has a plurality of terminal electrodes 40 (40a, 40b) arranged apart from each other and electrically connected to the internal electrodes 22 (22a, 22b) on at least the mounting surface 11 among the sides forming the surfaces of the element body 10. The mounting surface 11 is the surface facing the surface of the circuit board B when the multilayer ceramic capacitor 100 is mounted on the circuit board B. The terminal electrodes 40 can be connected to electrode pads on the surface of the circuit board B, for example, by solder. The method used to electrically connect the terminal electrodes 40 (40a, 40b) to the internal electrodes 22 (22a, 22b) is not limited. In the present embodiment, the terminal electrodes 40a, 40b are connected to the internal electrodes 22a, 22b by way of via conductors 23a, 23b. One end of the via conductors 23a, 23b penetrates the covering layer 31 on the positive side in the T direction to come into contact with the terminal electrodes 40a, 40b respectively. These connections may be realized via external conductors instead of via conductors 23a, 23b, as in the second embodiment described below. The multilayer ceramic capacitor 100 shown in FIG. 2 has two terminal electrodes 40, but the number of terminal electrodes in the multilayer ceramic capacitor 100 of the first aspect of the present invention is not limited to this number.

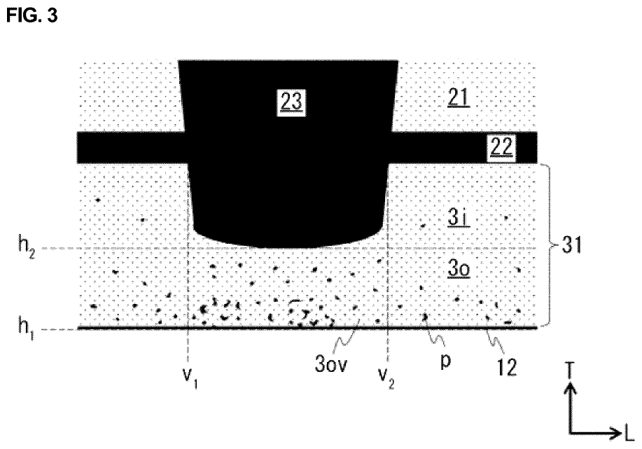

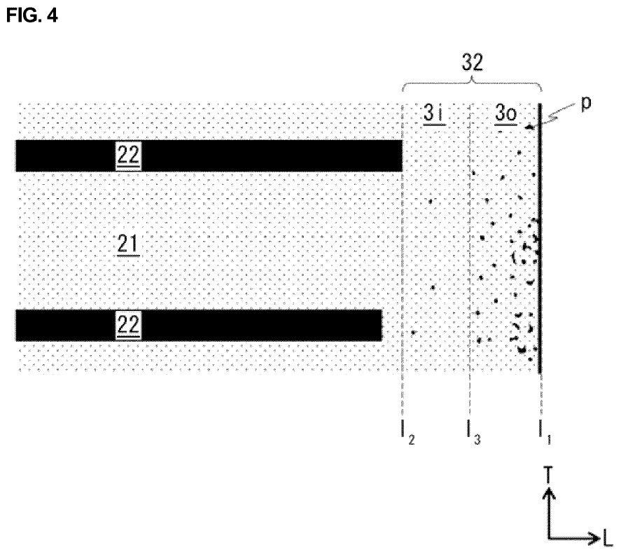

The multilayer ceramic capacitor 100 of the first embodiment includes voids p formed to satisfy the relational expression (1) below. Here, where Pₒ is the porosity of a surface layer portion 3o and Pᵢ is a porosity of an inner portion located 3i closer to the multilayer unit 20 than the surface layer portion 3o in at least some of the regions in the covering portion 31 or the margin portion 32 (Refer to FIGS. 3 and 4).

$${P}_{i} < {P}_{o} \qquad ( 1 )$$

Note that the multilayer ceramic capacitor 100 has an element body 10 in which the entire region of the covering portion 31 on the opposite side 12 opposite the mounting surface 11 satisfies relational expression (1) above. While the covering portion 31 and margin portion 32 on the mounting surface 11 side do not satisfy relational expression (1) above, the covering portion 31 and the margin portion 32 of the multilayer ceramic capacitor 100 of the first aspect of the present invention is not limited to this example. The locations satisfying relational expression (1) above may be the entire margin portion only, the entire covering portion 31 and margin portion 32, or only portions of some specific covering portions 31 or margin portions 32.

The maximum thickness of the element body 10 should be, for example, 20 μm or more and 200 μm or less, and preferably 30 μm or more and 180 μm or less, excluding the thickness of the terminal electrodes 40 (40a, 40b) from the T-direction dimension of the multilayer ceramic capacitor 100.

Because the multilayer ceramic capacitor 100 of the first embodiment has internal electrodes 22 (22a, 22b) and terminal electrodes 40 (40a, 40b) connected by way of via conductors 23 (23a, 23b), no external conductors are required on the opposite surface 12 opposite the mounting surface 11 or on the side surfaces perpendicular to the mounting surface 11 and the opposite surface 12 in the element body 10. Therefore, the multilayer ceramic capacitor 100 of the first embodiment is useful in that the element body dimensions can be reduced by the thickness of the external conductor.

Each component constituting the multilayer ceramic capacitor 100 in the first embodiment will now be described in detail.

### (Ceramic Layers)

Ceramic layers 21 are formed of ceramic. The composition of the ceramic is not particularly limited as long as it forms dense ceramic layers 21 when simultaneously fired with the internal electrodes 22 described below, and may be selected based to the characteristics required of the multilayer ceramic capacitor. Examples of ceramic compositions include those composed primarily of barium titanate (BaTiO₃), strontium titanate (SrTiO₃), and Ba_{1-x-y}CaₓSr_{y}Ti_{1-z}ZrO₃, which has a perovskite structure. The ceramic may contain additive elements along with the main components mentioned above. Examples of additive elements include at least one selected from Mo, Nb, Ta, W, Mg, Mn, V, and Cr, rare earth elements (Y, Sm, Eu, Gd, Tb, Dy, Ho, Er, Tm, and Yb), and Co, Ni, Li, B, Na, K, and Si. Additive elements may be present as individual elements or in the form of compounds such as oxides, nitrides, and carbides. In addition, the additive elements may be present in a solid solution state along with the primary components, or may form a different phase with the elements constituting the primary components or other additive elements.

### (Internal Electrodes)

The internal electrodes 22 (22a, 22b) are primarily composed of metal. The type of metal is not particularly limited, and examples include nickel (Ni), copper (Cu), palladium (Pd), platinum (Pt), silver (Ag), and gold (Au), as well as alloys of these metals. Among these metals, those containing nickel (Ni) as the primary constituent element are preferable because they can form dense ceramic layers 21 when the firing temperature is raised while firing the ceramic layers 21 due to their high heat resistance, and because they are relatively inexpensive. In the present specification, “primary constituent element” refers to the element with the highest content expressed as atomic percentage (atom %).

The internal electrodes 22 (22a, 22b) may contain, in addition to metal, ceramic particles having the same composition as the ceramic constituting the ceramic layers 21, or glass components.

### (Covering Portions and Margin Portions)

The covering portions 31 and the margin portions 32 both have a function of protecting the ceramic layers 21 and the internal electrodes 22. Materials for the covering portions 31 and the margin portions 32 are not limited as long as they have high electrical insulation properties and low permeability to moisture and other deteriorating factors. In order to uniformly provide shrinkage during firing and relieve internal stress in the multilayer ceramic capacitor 100, the primary component of the covering portions 31 and the margin portions 32 is preferably the same as the ceramic used to form the ceramic layers 21.

As mentioned above, the relational expression below is satisfied, where Pₒ is the porosity of a surface layer portion 3o and Pᵢ is a porosity of an inner portion 3i located closer to the multilayer unit 20 than the surface layer portion 3o in at least some of the regions in the covering portion 31 or the margin portion 32.

$${P}_{i} < {P}_{o} \qquad ( 1 )$$

This improves the toughness of the surface of the element body 10 and suppresses the occurrence of cracking and chipping when subjected to impacts. This is presumably because the voids in the surface layer portion 3o act as a deformation allowance, that is, a buffer, when stress is applied, thereby reducing the stress and suppressing local concentrations of stress.

The values of Pᵢ and Pₒ are not particularly limited as long as relational expression (1) above is satisfied. However, from the standpoint of significantly improving the toughness of the surface of element body 10, the value of Pₒ/Pᵢ is preferably 1.5 or more, more preferably 2 or more, and even more preferably 2.5 or more. Meanwhile, from the standpoint of fully realizing the original functions of covering portion 31 and the margin portion 32, which is to suppress the penetration of deleterious factors such as moisture into multilayer unit 20, the value of Pₒ/Pᵢ is preferably less than 100, more preferably less than 50, and even more preferably less than 10. The value of Pᵢ alone should be small and may even be 0% from the standpoint of fully realizing the original functions of covering portion 31 and the margin portion 32, which is to suppress the penetration of deleterious factors such as moisture into multilayer unit 20. The value of Pₒ alone should be 1% or more, preferably 2% or more, and even more preferably 3% or more from the standpoint of effectively improving the toughness of the surface of the element body 10. Meanwhile, from the standpoint of fully realizing the original functions of covering portion 31 and the margin portion 32, which is to suppress the penetration of deleterious factors such as moisture into multilayer unit 20, the value of Pₒ alone is preferably 10% or less, more preferably 9% or less, and even more preferably 8% or less. From the above, the value for Pₒ alone is preferably 2%≤Pₒ≤10%, more preferably 3%≤Pₒ≤9%, and even more preferably 4%≤Pₒ≤8%.

The multilayer ceramic capacitor 100 has no terminal electrodes 40 (40a, 40b) or conductors electrically connected thereto arranged on the opposite surface 12, which is the surface opposite the mounting surface 11 of the element body 10, as shown in FIG. 2, and when the covering portion 31 or margin portion 32 forming the opposite surface 12 as a whole satisfies relational expression (1) above, the effect of suppressing cracking and chipping by the improved toughness is significant. This is presumably due to the large exposed area of the opposite surface 12, which increases the likelihood of impact on the exposed portion, thereby causing a change in the probability of cracking and chipping occurring in the surface layer portion 3o due to differences in the porosity of the surface layer portion 30.

The multilayer ceramic capacitor 100, in addition to satisfying relational expression (1) above in at least some region of the covering portion 31 covering the end portions of the via conductors 23 (23a, 23b), should also satisfy relational expression (2) below, with respect to the porosity Pₒᵥ of the via surface layer portion 3ov, which is the region of the surface layer portion 3o of the covering portion 31 overlapping with the via conductors 23 (23a, 23b) inside the covering portion 31 when viewed from the laminating direction (T direction) of the multilayer unit 20.

$$Po < Pov \qquad ( 2 )$$

This results in a multilayer ceramic capacitor 100 with reduced capacitance variation and higher reliability. This is presumably due to the fact that, when stress is applied in the T direction to the via conductors 23 (23a, 23b) or to the interface between the via conductors 23 (23a, 23b) and the multilayer unit 20, voids p in the via surface layer portion 3ov function as a deformation allowance for the end portions of the via conductors 23 (23a, 23b) to relieve stress. suppressing crack formation at the interface between the via conductors 23 (23a, 23b) and the multilayer unit 20, and connection failures between the via conductors 23 (23a, 23b) and the internal electrodes 22 (22a, 22b).

As for the value of Pₒᵥ/Pₒ, from the standpoint of significantly suppressing capacitance variation, the value of Pₒᵥ/Pₒ is preferably 2 or more, more preferably 2.5 or more, and even more preferably 3 or more. Meanwhile, as for the value of Pₒᵥ/Pₒ, from the standpoint of fully realizing the original function of the covering portion 31 or the margin portion 32, which is to suppress the penetration of deleterious factors such as moisture into the multilayer unit 20, the value of Pₒ/Pᵢ is preferably 10 or less, more preferably 9 or less, and even more preferably 8 or less. The value of Pₒᵥ alone is preferably 2% or more, more preferably 3% or more, and even more preferably 4% or more in order to realize a significant effect in suppressing capacitance variation. Meanwhile, from the standpoint of fully realizing the original function of the covering portion 31 or the margin portion 32, which is to suppress the penetration of deleterious factors such as moisture into the multilayer unit 20, the value of Pₒᵥ alone is preferably 10% or less, more preferably 9% or less, and even more preferably 8% or less. Based on the above, for the Pₒᵥ value alone, 4%≤Pₒᵥ s 10% is preferable, 5%≤Pₒᵥ≤9% is even more preferable, and 6%≤Pₒᵥ≤8% is especially preferable.

Here, the values for Pᵢ, Pₒ, and Pₒᵥ are determined by the following procedure. First, a terminal electrode 40 formed on the mounting surface 11 of the multilayer ceramic capacitor 100 is removed to expose a via conductor 23 from the mounting surface 11. The terminal electrode 40 can be removed using polishing or acid dissolution. Next, the multilayer ceramic capacitor 100 is cut along a plane parallel to the laminating direction passing near the center of gravity of the via conductor 23 exposed from the mounting surface 11 to prepare an observation sample. This observation sample may be prepared by polishing a surface perpendicular to the mounting surface 11 to the vicinity of the center of gravity of the via conductor 23 exposed from the mounting surface 11. Next, the observation sample is embedded in resin so that the cut surface or polished surface is exposed, and the cut surface is polished to a mirror finish. Next, the mirror-finish cut surface or polished surface is observed under an optical microscope or scanning electron microscope (SEM), and an image is acquired in which the opposite surface 12, the internal electrode 22 closest to the opposite surface 12, and the via conductor 23 arranged in the covering portion 31 forming the opposite surface 12 are all within the same field of view, and a clear void is confirmed in the covering portion 31. Next, in the acquired image, (a) a line segment h₁ defining the opposite surface 12 is drawn, (b) a line segment h₂ parallel line segment h₁ and tangent to the end of the via conductor 23 is drawn, and (c) two line segments v₁ and v₂ perpendicular to line segment h₂ and tangent to the via conductor 23 in the covering portion 31 are drawn. Then, in the covering portion 31, the region located closer to the inner electrode 22 than segment h₂ is defined the inner portion 3i, and the region closer to the opposite surface 12 than line segment h₂ is defined as surface portion 30. In addition, the region located between line segment v₁ and line segment v₂ in the region defined as the surface layer portion 30 is defined as the via surface layer portion 3ov. Next, in each of the regions designated as the inner portion 3i, the surface portion 30, and via surface portion 3ov, the area of voids p is calculated using image analysis software, and the resulting values are divided by the total area of each region and multiplied by 100 to obtain Pᵢ, Pₒ, and Pₒᵥ. Note that when drawing line segment h₁, if the opposite surface 12 observed in the image forms a curve or jagged line, the curve or jagged line is approximated linearly and used as a line segment.

In addition, when determining the Pᵢ and Pₒ porosity values for the covering portion 31 on the margin portion 32 or the mounting surface 11 side, the following procedure is used. Note that the procedure described below explains the method for determining the void ratio of the margin portion 32, but the same procedure can also be applied to the covering portion 31 on the mounting surface 11. First, the multilayer ceramic capacitor 100 is cut along a plane that is perpendicular to the margin portion 32 that is the object of interest, parallel to the opposite surface, and at a distance from each surface that is between ⅓d and ⅔d of the distance d between the surfaces, and this is used as an observation sample. Next, the observation sample is embedded in resin so that the cut surface is exposed, and the cut surface is polished to a mirror finish. Next, the mirror-finish cut surface or polished surface is observed under an optical microscope or scanning electron microscope (SEM), and an image is acquired in which the surface of the margin portion 32 and the internal electrode 22 closest to this surface as shown in FIG. 4 are within the same field of view, and a clear void is confirmed in the margin portion 32. Next, in the acquired image, (d) line segment 11 defining the surface of margin portion 32 is drawn, (e) line segment 12 parallel to line segment 11 and adjacent to the end of the internal electrode 22 is drawn, and (f) line segment I₃ parallel to line segments 11 and 12 and equidistant from each of them is drawn. Then, in the margin portion 32, the region closer to line segment 12 than line segment I₃ is defined as the inner portion 3i, and the region closer to line segment 11 than line segment I₃ is defined as the surface layer portion 3o. Next, for the areas designated as the inner portion 3i and the surface layer portion 3o, the area of the voids p is calculated using image analysis software, and the resulting values were divided by the total area of each area and multiplied by 100 to obtain Pᵢ and Pₒ.

When the via surface layer portion 3ov satisfies relational expression (2) above, the percentage of cells containing voids p to the total number of cells preferably is 10% or more when the cross section parallel to the T direction is divided into square cells with a side length of 1 μm. This means that the voids p are widely distributed in the via surface layer portion 3ov, thereby making the capacitance variation suppressing effect more pronounced. This percentage is preferably 20% or more, and more preferably 30% or more.

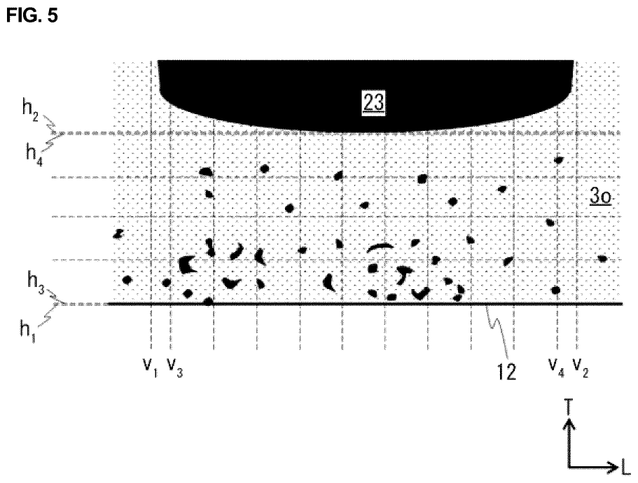

Here, the percentage of cells containing voids relative to the total number of cells in the cross section of the via surface layer portion 3ov is determined using the following procedure. First, like the procedure for determining Pᵢ, Pₒ, and Pₒᵥ values described above, a micrograph image of the cut surface or polished surface of an observation sample is obtained, and line segments h₁, h₂, v₁, and v₂ are drawn in the image. Next, the distance between line segments h₁ and h₂ is measured, the distance is divided by the length corresponding to 1 μm in the micrograph image, and the remainder is set as Hᵣ. Next, the distance between line segment v₁ and line segment v₂ is measured, the distance is divided by the length corresponding to 1 μm in the micrograph image, and the remainder is set as Vᵣ. In the micrograph image, as shown in FIG. 5, line segment h₃ is drawn parallel to line segment h1 at a distance of Hᵣ/2 from it, line segment h4 is drawn parallel to line segment h₂ at a distance of Hᵣ/2 from it, line segment v₃ is drawn parallel to line segment v₁ at a distance of Vᵣ/2 from it, and line segment v₄ is drawn parallel to line segment v₂ at a distance of Vᵣ/2 from it. Next, lines parallel to line h₃ at intervals corresponding to 1 μm in the micrograph image are drawn between line h₃ and line h₄. Also, lines parallel to line v₃ at intervals corresponding to 1 μm in the micrograph image are drawn between line v₃ and line v₄. Next, the total number of cells drawn inside the rectangular area enclosed by line segments h₃, h₄, v₃, and v₄ is counted, and the number of cells having gaps p inside them are counted. In a single void spans more than one cell, the void is considered to be present in both cells. Next, the number of cells with voids is divided by the total number of cells and multiplied by 100 to calculate the percentage of cells with voids relative to the total number of cells.

### (Via Conductors)

The via conductors 23 (23a, 23b) are composed primarily of metal, similar to the internal electrodes 22 (22a, 22b). The metals that can be used are the same metals as those used in the internal electrodes 22 (22a, 22b) described above. The composition of the via conductors may be different from that of the internal electrodes 22 (22a, 22b), but is preferably the same as that of the internal electrodes 22 (22a, 22b). When the via conductors (23a, 23b) and the internal electrodes 22 (22a, 22b) have the same composition, the amount of shrinkage caused by firing is uniform during production of the multilayer ceramic capacitor 100, thereby suppressing deformation. The resistivity of the conductive paths in the multilayer ceramic capacitor 100 are also uniform, thereby suppressing localized heating during use.

The diameter of the via conductors (23a, 23b) is not particularly limited, but in order to ensure the capacitance of the multilayer ceramic capacitor 100 while reducing electrical resistance and suppressing heat generation during circuit operation, the diameter is preferably 5 μm or more and 100 μm or less, and more preferably 10 μm or more and 50 μm or less.

### (Terminal Electrodes)

The material of the terminal electrodes 40 (40a, 40b) is not limited as long as it is a conductive material. Examples of materials include metals such as nickel (Ni), copper (Cu), tin (Sn), palladium (Pd), platinum (Pt), silver (Ag), and gold (Au), alloys containing any of these as the primary constituent element, and conductive resins.

The terminal electrodes 40 (40a, 40b) may include base conductors 41 in contact with the element body 10 and plated conductors 42 formed on the surface of the base conductors 41. Terminal electrodes 40 (40a, 40b) with this structure improve the bonding strength to the element body 10 by the base conductors 41, while improving solder wettability by the plated conductors 42 when the multilayer ceramic capacitor 100 is mounted on a circuit board B.

An example of a material for the base conductors 41 is Ni. The thickness of the base conductors 41 is, for example, 0.1 μm or more and 10 μm or less, and preferably 0.5 μm or more and 5 μm or less.

The plated conductors 42 may be formed with a single layer or multiple layers. When the plated conductors 42 have multiple layers, they preferably have two to four layers. The material and structure of plated conductors 42 can be a structure formed in the order Cu, Ni, and Sn. The thickness of the plated conductors 42 is, for example, 1 μm or more and 20 μm or less, and preferably 3 μm or more and 10 μm or less.

The area of the terminal electrodes 40 (40a, 40b), that is, the area of the terminal electrodes 40 (40a, 40b) as viewed from the direction perpendicular to the mounting surface 11 of the multilayer ceramic capacitor 100, is not particularly limited, but should be large enough to facilitate mounting of the capacitor on a circuit board B, but small enough to prevent short circuits between electrodes with different polarities. Preferably, the ratio of the total area of the terminal electrodes 40 to the area of the mounting surface 11 is 0.2 or more and 0.9 or less, and more preferably, 0.3 or more and 0.8 or less.

### Second Embodiment

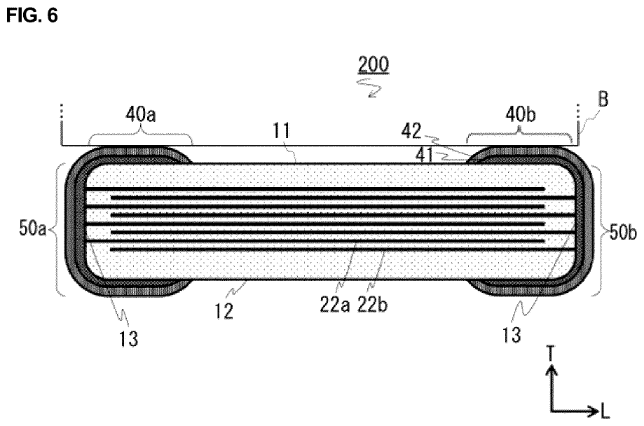

Another embodiment (second embodiment) of the multilayer ceramic capacitor in the first aspect of the present invention is one in which the internal electrodes are electrically connected to each other by external conductors. An example of the multilayer ceramic capacitor 200 in the second embodiment is shown in FIG. 6. In this multilayer ceramic capacitor 200, the internal electrodes 22 (22a, 22b) drawn out from the lead-out surfaces 13 of the element body 10 are electrically connected to each other by external conductors 50 (50a, 50b), and the external conductors 50 (50a, 50b) are electrically connected to the terminal electrodes 40 (40a, 40b) arranged on the mounting surface 11. Note that the multilayer ceramic capacitor 200 has a pair of end faces formed so that the external conductors 50 (50a, 50b) oppose each other, but a multilayer ceramic capacitor in the third embodiment may have an external conductor formed on only one end surface, or on the lead-out surface 13 without going around the opposite surface 12.

When determining the values for the porosity Pᵢ and Pₒ of the margin portion 32 or the covering portion 31 of the multilayer ceramic capacitor 200, the procedure for determining the porosity of the margin portion 32 described above is used or a procedure in which the margin portion 32 is replaced by the covering portion 31 in that procedure is used.

### Third Embodiment

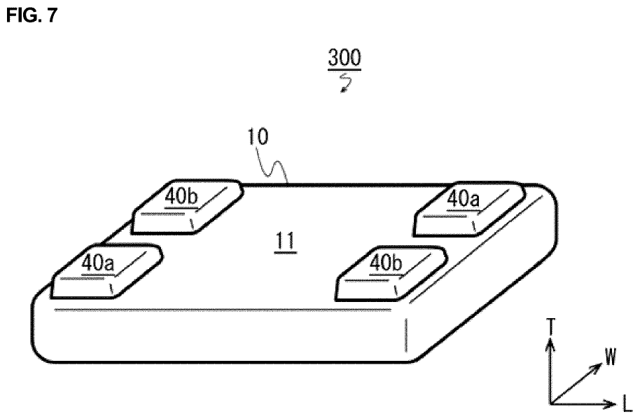

Another embodiment (third embodiment) of the multilayer ceramic capacitor in the first aspect of the present invention has four or more terminal electrodes arranged on the mounting surface. An example of a multilayer ceramic capacitor 300 in the third embodiment is shown in FIG. 7. Note that while the number of terminal electrodes 40 arranged on the mounting surface 11 of the multilayer ceramic capacitor 300 is four, the number of terminal electrodes arranged on the mounting surface 11 is not limited to this. The multilayer ceramic capacitor 300 has the advantage of reducing resistive heating because it can suppress the amount of current flowing through the via conductors 23 (23a, 23b) electrically connected to each terminal electrode 40 (40a, 40b). Also, when the polarities of the terminal electrodes 40 (40a, 40b) that are closest to each other on the mounting surface 11 are different, the directions in which the current flows through the via conductors 23 (23a, 23b) electrically connected to each terminal electrode 40 (40a, 40b) are opposite to each other between the closest via conductors 23 (23a, 23b). Therefore, the magnetic fields generated by the current cancel each other out, which has the advantage of reducing the equivalent series inductance (ESL). The ESL reducing effect is significant when the mounting surface 11 of the multilayer ceramic capacitor 400 has a shape close to a square, that is, when the ratio of W to L, that is, W/L, is 0.8 or greater and 1 or less, where among the two opposite surfaces parallel to the laminating direction of the multilayer unit 20, the distance in one direction, that is, the L-direction dimension, is L μm, and the spacing in the other direction, that is, the W-direction dimension, is W μm (where L≥W).

### [Method for Manufacturing Multilayer Ceramic Capacitor]

The multilayer ceramic capacitor 100, 200, 300 in the first aspect of the present invention can be manufactured by performing the following steps.

### [Preparation of Ceramic Powder (A)]

First, the ceramic powder is prepared. Commercially available ceramic powder can be used when appropriate. When preparing the ceramic powder, the raw material powders containing the constituent elements may be mixed together at the specified ratios and preliminary firing (pre-firing) performed. When mixing the raw material powders together at the predetermined ratios, additives such as the additive elements listed above and sintering aids may be added. However, these additives may also be added to the powder after pre-firing.

### [Preparation of Raw Sheets (B)]

Next, the ceramic powder is mixed with a binder and a dispersing medium to prepare a slurry, and the slurry is formed into a sheet to obtain a raw sheet.

The binder can be any one that can maintain the shape of the raw sheet and, during binder removal processing prior to firing, allows volatile substances to evaporate without leaving carbon or other residues. Examples of binders that can be used include polyvinyl alcohol-based, polyvinyl butyral-based, cellulose-based, urethane-based, and vinyl acetate-based binders. The amount of binder used is not particularly limited, but since it is to be removed in a subsequent step, it is desirable to use as little as possible within a range that allows the desired moldability and shape retention to be obtained and that also reduces raw material costs.

The dispersing medium can be one that does not cause agglomeration of the pre-fired powder and that enables the binder to be easily removed by volatilization, etc., after raw sheet molding described below. Examples of dispersing media that can be used include water and alcohol-based solvents.

The slurry may contain components such as dispersants, plasticizers, and thickeners to adjust the properties of the slurry.

The method used to mix the mixed powder with a binder and a dispersing medium is not particularly limited as long as it prevents the introduction of impurities and ensures that each component is uniformly mixed. One example is ball mill mixing.

Methods that can be used to form the prepared slurry into a sheet to obtain a raw sheet include conventional methods such as the doctor blade method and the die coating method.

### [Formation of Internal Electrode Patterns (C)]

Next, an internal electrode pattern containing metal is formed on the raw sheet. The internal electrode pattern can be formed by printing or coating an internal electrode paste in a predetermined pattern, or by forming a metal film in a predetermined pattern by vapor deposition or sputtering. The internal electrode pattern is formed with sufficient margin to ensure electrical insulation from the via conductor pattern formed later, with which it is not to make contact.

When forming an internal electrode pattern using internal electrode paste, the internal electrode paste used is obtained by mixing metal particles into a vehicle using a three-roll mill. The internal electrode paste may also contain glass frit or ceramic powder in addition to these components.

The types and amounts of binders and solvents included in the vehicle to be used are not limited, but should be selected after taking into consideration the viscosity of the internal electrode paste, ease of handling, and compatibility with the raw sheet.

Printing of the paste for the internal electrodes on the raw sheet can be performed, for example, using a screen mask with a predetermined internal electrode pattern. During printing, a space may be printed that will become a margin portion when made into a multilayer ceramic capacitor. Here, in order to make a margin portion that satisfies relational expression (1) above, a raw sheet may be used in which the ceramic powder content ratio at the position corresponding to the surface layer portion of the margin portion is lower than at the position corresponding to the inner portion of the margin portion.

### [Preparation of Raw Laminate (D)]

Next, a predetermined number of raw sheets with internal electrode patterns formed on them are laminated, and the raw sheets are bonded together by pressing to obtain a raw laminate. The laminating and bonding can be performed using conventional methods. For example, raw sheets can be laminated by heating them while pressing them in the laminating direction, and then heat-bonding them together using a binder.

In order to produce a multilayer ceramic capacitor in which at least some of the covering portion 31 satisfies relational expression (1) above, during laminating and pressing, a raw sheet may be added to the end portion in the laminating direction with a region that contains a lower percentage of ceramic powder than the raw sheet with the internal electrode pattern.

### [Formation of Via Conductor Pattern (E)]

When manufacturing a multilayer ceramic capacitor 100 in the first embodiment, holes are formed in the raw laminate, and a conductor paste is added to fill the holes and form a via conductor pattern. Conventional methods such as drilling and laser cutting can be used to form the holes. Among these, laser cutting is preferred because it produces smooth machined surfaces. Conventional methods such as injection using a syringe or printing using a metal mask can be used to add the conductive paste to fill the holes. Among these, printing using a metal mask is preferred due to its excellent filling properties for small holes. The same components as those used for the internal electrode paste described above can be used for the conductive paste, and the proportions of each component can be determined based on the filling properties for the holes.

### [Formation of Terminal Electrode Pattern (F)]

Next, a terminal electrode pattern is formed on at least one of the surfaces perpendicular to the laminating direction of the raw laminate (the mounting surface 11). At this time, a raw sheet that will become the covering portion 31 once the multilayer ceramic capacitor is formed can be applied so that it covers the via conductor pattern on the surface where the terminal electrode pattern is not formed. By making the raw sheet to be pressed at this time have a region with a lower ceramic powder content than the raw sheet on which the internal electrode pattern is formed, a multilayer ceramic capacitor can be obtained in which at least some the covering portion satisfies relational expression (1) above. By selectively reducing the ceramic powder content ratio of the raw sheet to be pressed at the location where the via conductor pattern is formed, a multilayer ceramic capacitor can be obtained in which the covering portion also satisfies relational expression (2) above. The terminal electrode pattern can be formed by printing or coating terminal electrode paste, or by forming metal film by vapor deposition or sputtering. At this time, the terminal electrode pattern may be formed using a mask with a predetermined pattern, or a paste film or metal film may be formed over the entire mounting surface of the raw laminate and the portions other than the terminal electrode pattern removed to form a pattern. Surface milling, barrel polishing, etc. can be used to remove parts other than the terminal electrode pattern. When removing the portions other than the terminal electrode pattern, removing portions of the surface of the raw laminate also allows recessed portions to be formed at positions corresponding to the mounting surface side intersection portions. When using terminal electrode paste to form a terminal electrode pattern, the same components as those used for the internal electrode paste described above can be used, and the proportions of each component can be determined so that a uniform pattern of a specified thickness can be obtained.

### [Preparation of Pre-Fired Chips (G)]

Next, the raw laminate is divided into individual multilayer ceramic capacitor shapes through a process called “chipping” to obtain pre-fired chips. Chipping can be performed using conventional methods with a dicing saw or a laser cutting machine. After separating the raw laminate into individual units and forming a surface exposing the internal electrode precursors, the surface may be coated with a material to the margin portions before using the individual units as pre-fired chips. Here, by using a material to form the margin portion that contains a lower percentage of ceramic powder than the raw sheet on which the internal electrode pattern is formed, a multilayer ceramic capacitor can be obtained in which at least some of the margin portion satisfies relational expression (1) above.

### [Removal of Binder (H)]

Next, the pre-fired chips are heated to volatilize and remove the binder. The heating conditions can be set after taking into consideration the volatilization temperature and content of the binder. In one example, the temperature is held at 200° C. to 500° C. for 5 to 20 hours in a nitrogen (N₂) atmosphere.

### [Firing of Pre-Fired Chips (I)]

Next, the pre-fired chips with the binder removed are heated to a specified temperature and fired. When setting the firing conditions, the firability of the ceramic powder and the heat resistance and oxidation resistance of the metals contained in the internal electrode pattern, via conductor pattern, and terminal electrode pattern should be taken into consideration. In one example of firing conditions, the temperature is held at 1100° C. to 1400° C. for 10 minutes to 2 hours in a reducing atmosphere that is a mixture of nitrogen (N₂), hydrogen (H₂), and water vapor (H₂O). After firing, a re-oxidation treatment is optionally performed by holding the temperature at 600° C. to 1000° C. in a nitrogen (N₂) gas atmosphere or a low-oxygen atmosphere.

### [Formation of External Conductors and Terminal Electrodes (J)]

When manufacturing a multilayer ceramic capacitor 200 in the second embodiment, step (E) above is omitted, and external conductors are formed by following step (I), or steps (E) and (F) are omitted, and external conductors and terminal electrodes are formed by following step (I). The method used to form the external conductors and terminal electrodes include applying conductive paste by printing or dipping before firing, or forming metal film by physical vapor deposition (PVD) such as vapor deposition.

The fired body obtained in this manner can be used as a multilayer ceramic capacitor 100, 200, 300 as is, or a conductive layer can be formed on the surface of the terminal electrode pattern by plating before using the fired body as a multilayer ceramic capacitor.

### [Circuit Board]

The circuit board B according to the second aspect of the present invention is mounted with a multilayer ceramic capacitor 100, 200, 300 according to the first aspect. This circuit board B has excellent durability and reliability, because of the improved toughness of the surface of the element body 10 in the multilayer ceramic capacitor 100, 200, 300.

The present invention is able to provide a multilayer ceramic capacitor in which the surface of the element body has improved toughness and a circuit board on which this multilayer ceramic capacitor has been mounted. As a result, the present invention is useful in that it can provide a circuit board with excellent durability and reliability.

1. A multilayer ceramic capacitor comprising:
a multilayer unit obtained by alternately laminating ceramic layers and internal electrodes composed primarily of metal;
a cuboid element body having a pair of covering portions arranged at both ends of the multilayer unit in the laminating direction and covering surfaces of the multilayer unit, and margin portions covering at least some of the end portions of the ceramic layers and the end portions of the internal electrodes in the multilayer unit, and connecting the pair of covering portions to each other; and
a plurality of terminal electrodes electrically connected to the internal electrodes, and arranged apart from each other on at least a mounting surface out of the surfaces forming the surfaces of the element body,
wherein the mounting surface is a surface facing the circuit board on which the multilayer ceramic capacitor is to be mounted, and
relational expression (1) below is satisfied, where Pₒ is the porosity of a surface layer portion and Pᵢ is a porosity of an inner portion located closer to the multilayer unit than the surface layer portion in at least some of the regions in the covering portion or the margin portion
$${P}_{i} < {P}_{o} . \qquad ( 1 )$$

2. The multilayer ceramic capacitor according to claim 1, wherein neither the terminal electrodes nor the conductors electrically connected thereto are arranged on the opposite surface, which is the surface opposite the mounting surface in the element body, and the entire covering portion or margin portion forming the opposite surface satisfies relational expression (1) above.

3. The multilayer ceramic capacitor according to claim 1, wherein the element body further comprises a plurality of via conductors arranged to penetrate the ceramic layers in the laminating direction of the multilayer unit and electrically connected to the internal electrodes, one end of the via conductor reaching the surface of one of the pair of covering portions and electrically connected to the terminal electrodes, and the other end of the via conductor covered by the other of the pair of covering portions.

4. The multilayer ceramic capacitor according to claim 3, wherein at least some of a region in the covering portion that covers the end portions of the via conductors satisfies relational expression (1) above, and of the surface layer portion in the covering portion, the porosity Pₒᵥ of the via surface layer portions, which are the regions overlapping the via conductors located in the covering portion when viewed from the laminating direction of the multilayer unit, satisfies the following relational expression (2)
$${P}_{o} < {P}_{ov} . \qquad ( 2 )$$

5. The multilayer ceramic capacitor according to claim 4, wherein, in the via surface layer portion, when a cross section parallel to the laminating direction of the multilayer unit is divided into square cells with each side being 1 μm, the percentage of the number of cells with voids to the total number of cells is 10% or more.

6. The multilayer ceramic capacitor according to claim 1, wherein the number of terminal electrodes is equal to or greater than 4.

7. The multilayer ceramic capacitor according to claim 6, wherein the polarity of each terminal electrode is different from that of the other terminal electrodes closest thereto on the mounting surface.

8. A circuit board on which is mounted a multilayer ceramic capacitor according to claim 1.
